(19) United States
(12) Patent Application Publication
(10) Pub. No.: US 2026/0206323 A1
(43) Pub. Date: Jul. 16, 2026

(54) TARGET PATTERN AND PATTERNING METHOD OF FORMING TARGET PATTERN

(71) Applicant: Winbond Electronics Corp., Taichung City (TW)

(72) Inventor: Wen-Peng Huang, Tainan (TW)

(73) Assignee: Winbond Electronics Corp., Taichung City (TW)

(21) Appl. No.: 19/396,370

(22) Filed: Nov. 21, 2025

(30) Foreign Application Priority Data
Dec. 23, 2024 (TW) 113150118

(51) Int. Cl. H10D 89/10; G03F 1/36; H10P 50/00; H10P 76/40

(52) U.S. Cl. CPC H10D 89/10; G03F 1/36; H10P 50/695; H10P 76/405; H10P 76/4085

(57) ABSTRACT

A target pattern including a main pattern and a compensation pattern. The compensation pattern is located at least one end of the main pattern to compensate for a rounded feature of the main pattern, wherein the compensation pattern has an approximately rectangular pattern. A patterning method of forming a target pattern is also provided.

### CROSS-REFERENCE TO RELATED APPLICATION

This application claims the priority benefit of Taiwan application serial no. 113150118, filed on Dec. 23, 2024. The entirety of each of the above-mentioned patent applications is hereby incorporated by reference herein and made a part of this specification.

### BACKGROUND

### Technical Field

The invention relates to a memory device and a forming method thereof, and in particular, to a target pattern and a patterning method of forming target pattern.

### Description of Related Art

In the array area and the peripheral area of the memory device, target patterns are formed by performing different patterning methods.

For the array area of the memory device, the Self Alignment Double Patterning (SADP) process is used to form the regularly arranged target pattern. For the peripheral area of the memory device, the Litho Etching Litho Etching (LELE) process is used to form the target pattern. However, the target pattern formed by the LELE process is prone to corner rounding at its ends due to the Optical Proximity Effect (OPE). Based on this, when the contact window contacts the end of the target pattern formed by the LELE process, poor electrical connection is likely to occur, thereby affecting the reliability of the memory device.

### SUMMARY

The disclosure provides a target pattern, which includes a memory device having the target pattern.

The target pattern of the disclosure includes a main pattern and a compensation pattern. The compensation pattern is located at least one end of the main pattern to compensate for a rounded feature of the main pattern, wherein the compensation pattern has an approximately rectangular pattern.

The disclosure provides a patterning method of forming target pattern, which can reduce the corner rounding phenomenon of the edge of the formed target pattern, so that the memory device including the target pattern has relatively good reliability.

The patterning method of forming target pattern of the disclosure includes the following steps. A first core pattern is formed on a stacked structure, wherein the stacked structure includes a target layer, a mask layer and a spacer material layer stacked in sequence. A first spacer is formed in an opening of the first core pattern. The first spacer is used to perform the etching process on the spacer material layer to form a spacer material pattern. A second core pattern is formed on the mask layer. A second spacer is formed in an opening of the second core pattern. The second spacer is used to perform the etching process on the spacer material pattern to form a spacer pattern. A patterned photoresist layer is formed on the mask layer, wherein an opening of the patterned photoresist layer partially overlaps with the spacer pattern. The patterned photoresist layer is used to perform the etching process on the mask layer. The spacer pattern and the remaining mask layer are used to perform the etching process on the target layer to form the target pattern, wherein the spacer pattern overlaps with the remaining mask layer. A contour of at least one end of the target pattern is transferred by the spacer pattern, so that the at least one end of the target pattern has an approximately rectangular pattern.

Based on above, in the patterning method of the target pattern of the disclosure, the contour of the at least one end of the target pattern can be transferred by the spacer pattern, so that the at least one end of the target pattern has an approximately rectangular pattern. Based on this, the at least one end of the target pattern having the rounded feature can be compensated. In this way, it can reduce the possibility that the contact window is not fully in contact with the end of the target pattern, thereby improving the reliability of the memory device including the target pattern.

### BRIEF DESCRIPTION OF THE DRAWINGS

FIG. 1 is a partial top view schematic diagram of a patterning method of a target pattern according to an embodiment of the disclosure.

FIG. 2A to FIG. 2H illustrate a partial cross-sectional flow chart of the patterning method of the target pattern of the first embodiment of the disclosure.

FIG. 3A is a top view schematic diagram of a mask for forming the target pattern according to the first embodiment of the disclosure.

FIG. 3B is a top view schematic diagram of the target pattern according to the first embodiment of the disclosure.

FIG. 4A to FIG. 4E illustrate a partial cross-sectional flow chart of the patterning method of the target pattern of the second embodiment of the disclosure.

FIG. 5A is a top view schematic diagram of a mask for forming the target pattern according to the second embodiment of the disclosure.

FIG. 5B is a top view schematic diagram of the target pattern according to the second embodiment of the disclosure.

FIG. 6A is a top view schematic diagram of a mask for forming the target pattern according to the third embodiment of the disclosure.

FIG. 6B is a top view schematic diagram of the target pattern according to the third embodiment of the disclosure.

FIG. 7A is a top view schematic diagram of a mask for forming the target pattern according to the fourth embodiment of the disclosure.

FIG. 7B is a top view schematic diagram of the target pattern according to the fourth embodiment of the disclosure.

FIG. 8A is a top view schematic diagram of a mask for forming the target pattern according to the fifth embodiment of the disclosure.

FIG. 8B is a top view schematic diagram of the target pattern according to the fifth embodiment of the disclosure.

### DESCRIPTION OF THE EMBODIMENTS

The following embodiments are listed and described in detail with the accompanying drawings, but the embodiments provided are not intended to limit the scope of the present invention. In addition, the drawings are for illustrative purposes only and are not drawn to original size. In order to facilitate understanding, the same components will be indicated by the same symbols in the following description.

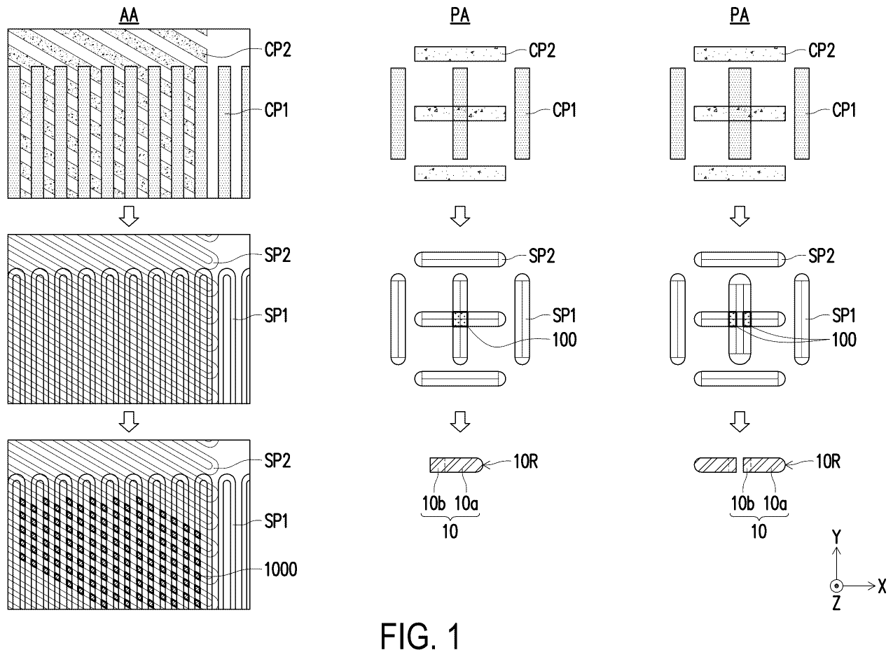

Referring to FIG. 1, FIG. 1 shows a patterning method for forming a target pattern 1000 and a target pattern 10 in an array area AA and a peripheral area PA respectively.

First, a plurality of first core patterns CP1 and a plurality of second core patterns CP2 are formed on a target layer (not shown) using a corresponding mask structure (not shown). In the array area AA, the first core patterns CP1 are arranged, for example, in a direction X, and the second core patterns CP2 are arranged, for example, in a specific direction, wherein the specific direction may be neither parallel nor perpendicular to the direction X. In the peripheral area PA, the first core patterns CP1 are arranged, for example, in the direction X, and the second core patterns CP2 are arranged, for example, in a direction Y, wherein the direction X may be perpendicular to the direction Y.

After that, a Self-Alignment Double Patterning (SADP) process is performed twice to form a first spacer SP1 and a second spacer SP2 on the side walls of the first core patterns CP1 and the second core patterns CP2 respectively.

Then, the first spacer SP1 and the second spacer SP2 are used to form the target pattern 1000 and the target pattern 10 in the array area AA and the peripheral area PA respectively. In details, in the array area AA, the first spacer SP1 and the second spacer SP2 can be used as a mask to perform the etching process on the target layer to form multiple regularly arranged target patterns 1000, wherein the target patterns 1000 may be, for example, landing pads, but the disclosure is not limited thereto. In the peripheral area PA, the first spacer SP1 and the second spacer SP2 can be used as a mask to perform the etching process on the spacer material layer (not shown) to form at least one spacer pattern 100. Afterwards, the spacer pattern 100 and the mask layer located below (for example, a mask layer N1 shown in the following embodiment) can be used as masks to perform the etching process on the target layer to form the target pattern 10, wherein the target pattern 10 may be a peripheral circuit, for example, a trace and a contact pad, but the disclosure is not limited thereto. In the embodiment, the target pattern 10 includes a main pattern 10a and a compensation pattern 10b. The shape of the compensation pattern 10b is transferred, for example, by the spacer pattern 100, wherein the compensation pattern 10b is, for example, located at least one end of the main pattern 10a to compensate for a rounded feature 10R of the main pattern 10a, so that the corresponding end of the target pattern 10 may have an approximately rectangular pattern.

The following will introduce various embodiments of forming the target pattern 10 in the peripheral area PA, but the disclosure is not limited thereto.

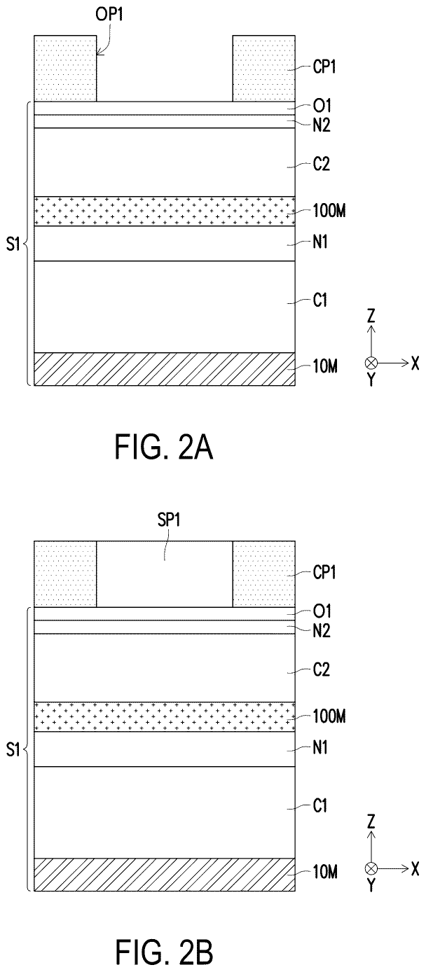

Referring to FIG. 2A, the first core pattern CP1 is formed on a stacked structure S1. The stacked structure S1 may include a substrate (not shown), a target layer 10M, a carbide layer C1, a mask layer N1, a spacer material layer 100M, a carbide layer C2, a mask layer N2, and an oxide layer O1 stacked in sequence in the direction Z.

The substrate may be, for example, a semiconductor substrate. In some embodiments, the material of the substrate may include silicon, doped silicon, germanium, silicon germanium, semiconductor compound, other suitable semiconductor materials, or a combination thereof.

The target layer 10M may be, for example, a material layer for forming the peripheral circuit. For example, the target layer 10M can be a material layer for forming traces and/or contact pads. In some embodiments, the material of the target layer 10M is a conductive material, which may include a metal material.

In some embodiments, the material of the carbide layer C1 can be diamond-like carbon (DLC) or amorphous carbon.

In some embodiments, the material of the mask layer N1 may include nitride. For example, the material of the mask layer N1 can be silicon oxynitride, silicon nitride, or other suitable nitrides.

The material of the spacer material layer 100M may include oxide. In some embodiments, the material of the spacer material layer 100M can be silicon oxide or tetraethyl siloxane.

In some embodiments, the material of the carbide layer C2 can be spin-on-carbon (SoC).

In some embodiments, the material of the mask layer N2 may include nitride. For example, the material of the mask layer N2 can be silicon oxynitride or silicon nitride.

In some embodiments, the material of the oxide layer O1 can be silicon oxide, tetraethyl siloxane.

In some embodiments, the material of the first core pattern CP1 may be, for example, a patterned photoresist. The first core pattern CP1 has an opening OP1 exposing a portion of the oxide layer O1.

Referring to FIG. 2B, the first spacer SP1 is formed in the opening OP1 of the first core pattern CP1. The method for forming the first spacer SP1 includes the following steps. First, a first spacer material layer (not shown) may be formed on the first core pattern CP1 and in the opening OP1 of the first core pattern CP1 by performing a chemical vapor deposition process. After that, the first spacer material layer on the first core pattern CP1 may be removed by performing an etch-back process to form the first spacer SP1 in the opening OP1 of the first core pattern CP1.

Referring to FIG. 2C, the first spacer SP1 is used as a mask to perform the etching process on the spacer material layer 100M to form a spacer material pattern 100M′. In details, first, before the first spacer SP1 is used to perform the etching process on the spacer material layer 100M, the first core pattern CP1 may be removed by a stripping process. After that, use the first spacer SP1 is used as a mask to perform the etching process on the stacked structure S1 to sequentially remove parts of the oxide layer O1, the mask layer N2, the carbide layer C2 and the spacer material layer 100M, wherein the mask layer N1 can serve as an etching stop layer. Then, the first spacer SP1 and the remaining oxide layer O1, the mask layer N2 and the carbide layer C2 are removed to expose the spacer material pattern 100M′. In general, in this step, the pattern of the first spacer SP1 is transferred to the spacer material layer 100M to form the spacer material pattern 100M′, which is the first self-alignment double patterning process.

Referring to FIG. 2D, a carbide layer C3, a mask layer N3, an oxide layer O2 and the second core pattern CP2 are sequentially formed on the mask layer N1, and the second spacer SP2 is formed in an opening OP2 of the second core pattern CP2, wherein the carbide layer C3 covers the spacer material pattern 100M′. The material respectively included in the carbide layer C3, the mask layer N3, the oxide layer O2, the second core pattern CP2, and the second spacer SP2 may be the same as or similar to, for example, the material respectively included in the carbide layer C2, the mask layer N2, the oxide layer O1, the first core pattern CP1, and the first spacer SP1, which will not be repeated here. Besides, the method of forming the second spacer SP2 in the opening OP2 of the second core pattern CP2 may be the same as or similar to the method of forming the first spacer SP1 in the opening OP1 of the first core pattern CP1, which will not be repeated here.

Referring to FIG. 2E, first, the second spacer SP2 is used as a mask to perform the etching process on the spacer material pattern 100M′ again to form the spacer pattern 100.

In details, first, before the second spacer SP2 is used to perform the etching process on the spacer material pattern 100M′ again, the second core pattern CP2 may be removed by a stripping process. After that, the second spacer SP2 is used to perform the etching process to sequentially remove a portion of the oxide layer O2, the mask layer N3, the carbide layer C3, and the spacer material pattern 100M′, wherein the mask layer N1 can serve as an etching stop layer. Then, the second spacer SP2 and the remaining oxide layer O2, the mask layer N3 and the carbide layer C3 are removed to expose the spacer pattern 100. In general, in this step, the pattern of the second spacer SP2 is transferred to the spacer material pattern 100M′ to form the spacer pattern 100, which is the second self-alignment double patterning process.

Referring continuously to FIG. 2E, after that, a carbide layer C4, a mask layer N4, an oxide layer O3, a polysilicon layer PS, a carbide layer C5, an anti-reflection layer AR and a patterned photoresist layer PR are sequentially formed on the mask layer N1, wherein the carbide layer C4 covers the spacer pattern 100. The patterned photoresist layer PR has, for example, an opening OP3. In the embodiment, the patterned photoresist layer PR has the opening OP3, and the opening OP3 partially overlaps with the spacer pattern 100 in the direction Z.

Referring to FIG. 2F, the patterned photoresist layer PR is used as a mask to perform the etching process to sequentially remove portions of the anti-reflection layer AR, the carbide layer C5, the polysilicon layer PS, the oxide layer O3, the mask layer N4, the carbide layer C4 and the mask layer N1, wherein the carbide layer C1 can serve as an etching stop layer. Then, the patterned photoresist layer PR and the remaining anti-reflection layer AR, carbide layer C5, polysilicon layer PS, oxide layer O3 and mask layer N4 are removed. In the embodiment, the spacer pattern 100 is not removed in the etching process and can protect the portion of the mask layer N1 located thereunder. Based on this, the remaining carbide layer C4 may expose a portion of the carbide layer C1 and a portion of the spacer pattern 100.

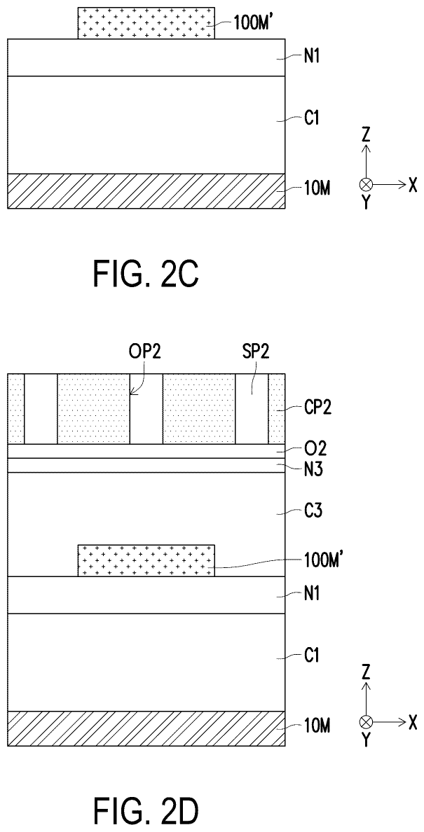

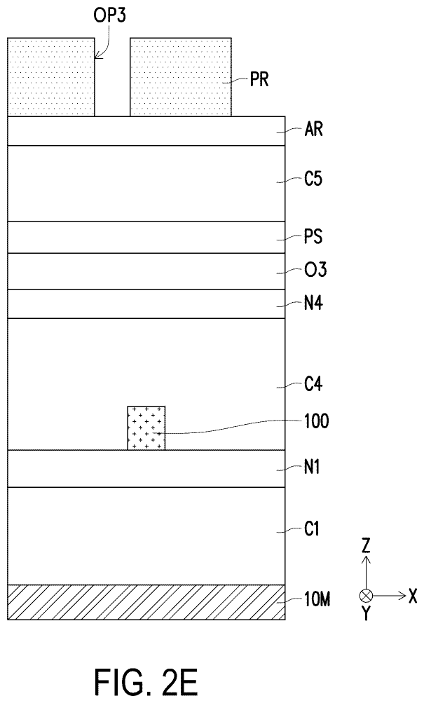

Referring to FIG. 2G and FIG. 3A, the spacer pattern 100 and the remaining carbide layer C4 are used as masks to perform the etching process to remove a portion of the carbide layer C1, wherein the target layer 10M can serve as an etching stop layer. Then, the remaining carbide layer C4 is removed. Referring to FIG. 3A, in the embodiment, two ends of the remaining mask layer N1 have rounded features N1R due to the Optical Proximity Effect (OPE), and the spacer pattern 100 overlaps with one end of the remaining mask layer N1 in the direction Z.

Referring to FIG. 2H and FIG. 3B, the spacer pattern 100 and the remaining mask layer N1 are used as masks to perform the etching process to remove a portion of the target layer 10M to form the target pattern 10 and the target pattern 12. In the embodiment, the contour of one end of the target pattern 10 is transferred by the spacer pattern 100, so that one end of the target pattern 10 has an approximately rectangular pattern.

In details, in the embodiment, the target pattern 10 includes the main pattern 10a and the compensation pattern 10b. The end of the main pattern 10a has the rounded feature 10R, for example, due to the OPE. The compensation pattern 10b is, for example, located at one end of the main pattern 10a and overlaps with the spacer pattern 100 in the direction Z. Therefore, the shape of the compensation pattern 10b can be transferred through the spacer pattern 100 to compensate for the rounded feature 10R of the main pattern 10a, so that the corresponding end of the target pattern 10 can have an approximately rectangular pattern. Since the target pattern 12 does not overlap with the spacer pattern 100 in the direction Z, both ends of the target pattern 12 may have a rounded feature 12R.

Referring continuously to FIG. 3B, in some embodiments, a contact window CT1 expected to contact one end of the target pattern 10 includes the compensation pattern 10b. Therefore, by forming the compensation pattern 10b, the target pattern 10 can be electrically connected to the contact window CT1, and the contact window CT1 and the end of the compensation pattern 10b of the target pattern 10 can be completely in contact, thereby increasing the reliability of the memory device (not shown) which includes the target pattern 10 of the compensation pattern 10b. In addition, in some embodiments, the portion of the target pattern 12 that is expected to contact a contact window CT2 is not its end, so the target pattern 12 may not include the compensation pattern.

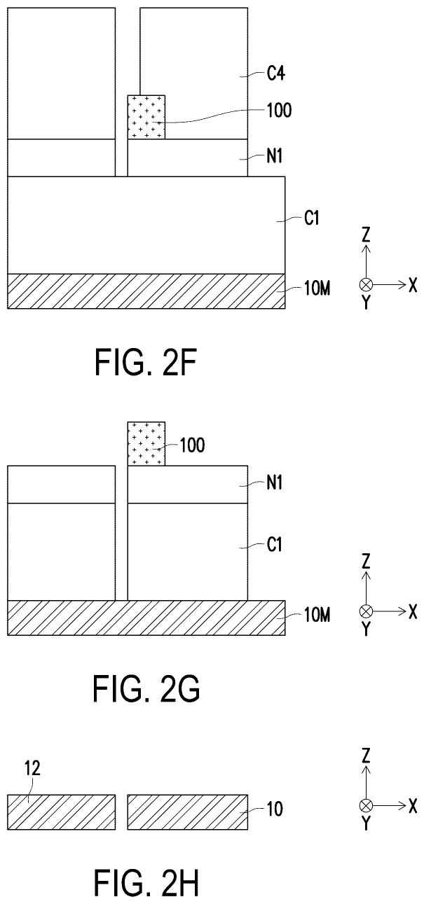

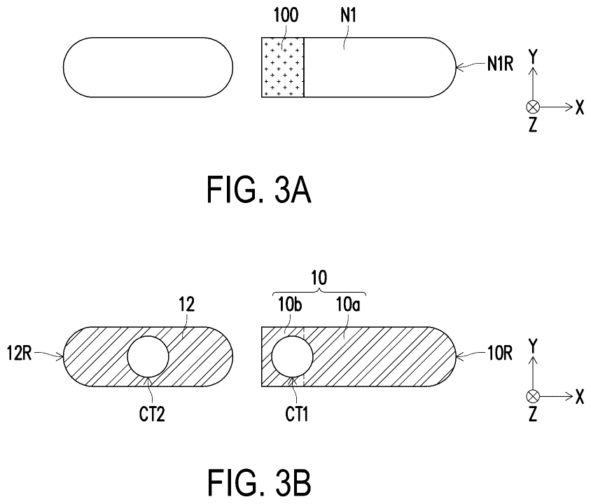

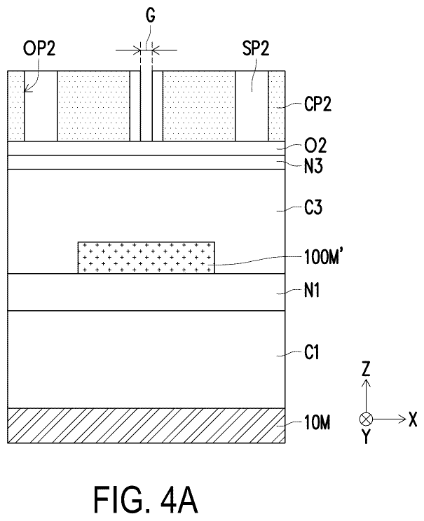

The embodiments of FIG. 4A to FIG. 4E can each use the component numbers and partial contents of the embodiments of FIG. 2D to FIG. 2H, the embodiment of FIG. 5A can each use the component numbers and partial contents of the embodiment of FIG. 3A, and the embodiment of FIG. 5B can each use the component numbers and partial contents of the embodiment of FIG. 3B, wherein the same or similar component numbers are used to represent the same or similar components, and descriptions of the same technical content are omitted.

The process steps shown in FIG. 4A can be performed after the process steps shown in FIG. 2C. Referring to FIG. 4A, the carbide layer C3, the mask layer N3, the oxide layer O2 and the second core pattern CP2 are sequentially formed on the mask layer N1, and the second spacer SP2 is formed in the opening OP2 of the second core pattern CP2, wherein the carbide layer C3 covers the spacer material pattern 100M′. The detailed description of the carbide layer C3, the mask layer N3, the oxide layer O2 and the second core pattern CP2 may refer to the above embodiment, which will not be repeated here.

In the embodiment, there is a gap G between the adjacent second spacers SP2, wherein the gap G exposes a portion of the oxide layer O2 and overlaps with the spacer material pattern 100M′ in the direction Z. The rest of the introduction about the second spacer SP2 may refer to the above embodiment, which will not be repeated here.

Referring to FIG. 4B, first, the second spacer SP2 is used as a mask to perform the etching process again on the spacer material pattern 100M′ to form two spacer patterns 100.

In details, first, before using the second spacer SP2 to perform the etching process again on the spacer material pattern 100M′, the second core pattern CP2 can be removed by using a stripping process. After that, the second spacer SP2 is used to perform the etching process to sequentially remove a portion of the oxide layer O2, the mask layer N3, the carbide layer C3, and the spacer material pattern 100M′, wherein the mask layer N1 can serve as an etching stop layer. Then, the second spacer SP2 and the remaining oxide layer O2, the mask layer N3 and the carbide layer C3 are removed to expose the spacer pattern 100. In general, in this step, the pattern of the second spacer SP2 is transferred to the spacer material pattern 100M′, thereby forming two spacer patterns 100.

Referring continuously to FIG. 4B, the carbide layer C4, the mask layer N4, the oxide layer O3, the polysilicon layer PS, the carbide layer C5, the anti-reflection layer AR and the patterned photoresist layer PR are sequentially formed on the mask layer N1, wherein the carbide layer C4 covers the spacer pattern 100. The patterned photoresist layer PR has, for example, an opening OP4. In the embodiment, the patterned photoresist layer PR has the opening OP4, and the opening OP4 partially overlaps with the two spacer patterns 100 in the direction Z.

Referring to FIG. 4C, the patterned photoresist layer PR is used as a mask to perform the etching process to sequentially remove portions of the anti-reflection layer AR, the carbide layer C5, the polysilicon layer PS, the oxide layer O3, the mask layer N4, the carbide layer C4, and the mask layer N1, wherein the carbide layer C1 can be used as an etching stop layer. Then, the patterned photoresist layer PR and the remaining anti-reflection layer AR, carbide layer C5, polysilicon layer PS, oxide layer O3 and mask layer N4 are removed. In the embodiment, the two spacer patterns 100 are not removed in the etching process and can protect the portion of the mask layer N1 located thereunder. Based on this, the remaining carbide layer C4 may expose a portion of the carbide layer C1 and a portion of the spacer pattern 100.

Referring to FIG. 4D and FIG. 5A, the spacer pattern 100 and the remaining carbide layer C4 are used as masks to perform the etching process to remove a portion of the carbide layer C1, wherein the target layer 10M can serve as an etching stop layer. Then, the remaining carbide layer C4 is removed. In the embodiment, the remaining end of the mask layer N1 has the rounded features N1R due to OPE, and the two spacer patterns 100 each overlap with one end of the corresponding mask layer N1 in the direction Z.

Referring to FIG. 4E and FIG. 5B, the spacer pattern 100 and the remaining mask layer N1 are used as masks to perform the etching process to remove a portion of the target layer 10M to form the two target patterns 10. In the embodiment, the target pattern 10 includes the main pattern 10a and the compensation pattern 10b. The end of the main pattern 10a has the rounded feature 10R due to, for example, OPE. The compensation pattern 10b is, for example, located at one end of the main pattern 10a and overlaps with the spacer pattern 100 in the direction Z. Therefore, the shape of the compensation pattern 10b can be transferred through the spacer pattern 100 to compensate for the rounded feature 10R of the main pattern 10a, so that the corresponding end of the target pattern 10 may have an approximately rectangular pattern.

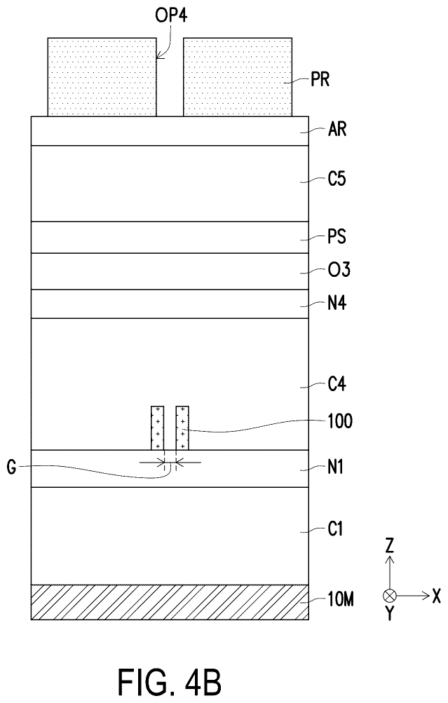

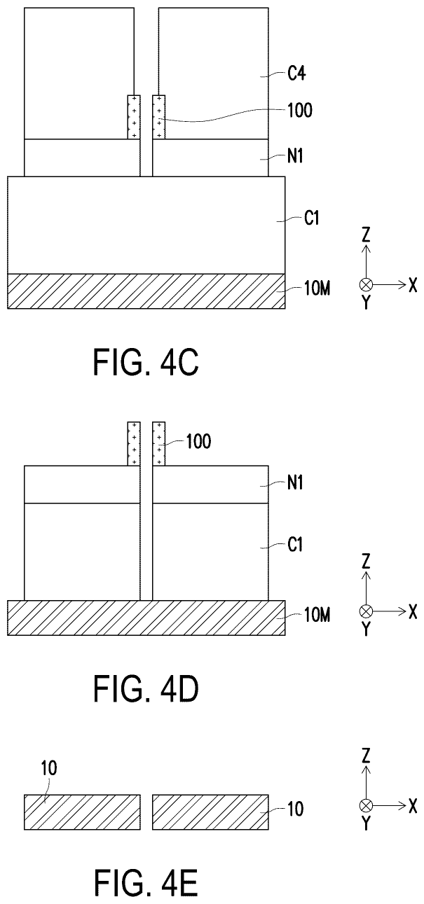

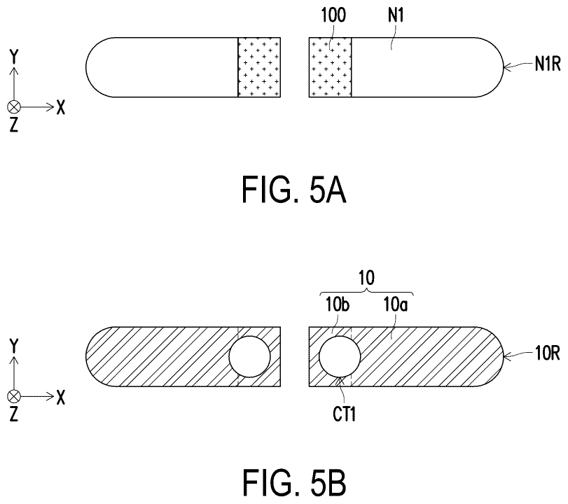

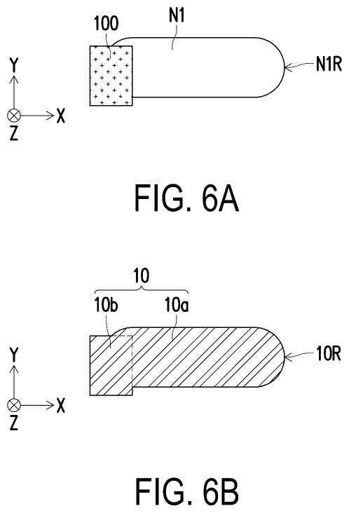

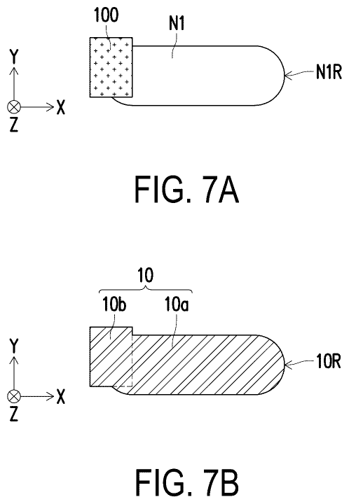

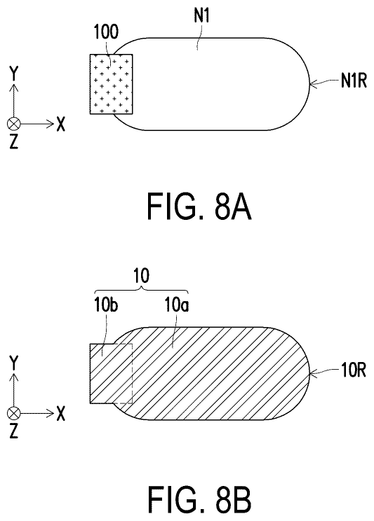

FIG. 6A, FIG. 7A and FIG. 8A may use the component numbers and some contents of the embodiment of FIG. 3A, wherein the same or similar numbers are used to represent the same or similar components, and the descriptions of the same technical content are omitted. FIG. 6B, FIG. 7B and FIG. 8B may use the component numbers and some contents of the embodiment of FIG. 3B, wherein the same or similar numbers are used to represent the same or similar components, and the descriptions of the same technical content are omitted.

Referring to FIG. 6A and FIG. 6B, compared with the above embodiment, the spacer pattern 100 of the embodiment may be slightly shifted relative to the mask layer N1 in a direction opposite to the direction Y. Based on this, the compensation pattern 10b of the target pattern 10 of the embodiment is also shifted in the direction opposite to the direction Y relative to the main pattern 10a.

Referring to FIG. 7A and FIG. 7B, compared with the above embodiment, the spacer pattern 100 of the embodiment is shifted relative to the mask layer N1 in the direction Y, so that the end of the portion of the mask layer N1 corresponding to the spacer pattern 100 may have the rounded features N1R. Besides, compared with the above embodiment, the compensation pattern 10b of the target pattern 10 of the embodiment is also shifted in the direction Y, so that the other end of the main pattern 10a can retain part of the rounded feature 10R. In details, in the embodiment, one end of the main pattern 10a has the rounded feature 10R, and the other end of the main pattern 10a is composed of an approximately rectangular pattern (transferred from the spacer pattern 100) and a portion of the rounded feature 10R. It is worth mentioning that the compensation pattern 10b of the target pattern 10 may be further shifted in the direction Y, so that the other end of the main pattern 10a has more rounded features 10R, but the disclosure is not limited thereto.

Referring to FIG. 8A and FIG. 8B, compared with the above embodiment, the mask layer N1 of the embodiment has a relatively large size in the direction Y, so the end of the portion of the mask layer N1 corresponding to the spacer pattern 100 may have the rounded features N1R. Besides, compared with the above embodiment, the main pattern 10a of the target pattern 10 of the embodiment also has a relatively large size in the direction Y. Since the compensation pattern 10b does not completely compensate the rounded feature 10R at one end of the main pattern 10a, one end of the main pattern 10a can retain part of the rounded feature 10R. In details, in the embodiment, one end of the main pattern 10a has the rounded feature 10R, and the other end of the main pattern 10a is composed of an approximately rectangular pattern (transferred from the spacer pattern 100) and a portion of the rounded feature 10R, wherein part of the rounded feature 10R is located on both sides of the approximately rectangular pattern in the direction Y.

In summary, in the patterning method of the target pattern of the disclosure, the contour of at least one end of the target pattern can be shifted by a spacer pattern, so that at least one end of the target pattern has the approximately rectangular pattern. Based on this, the rounded feature of at least one end of the target pattern can be compensated, which can reduce the possibility that the contact window is not fully in contact with the end of the target pattern, thereby improving the reliability of the memory device including the target pattern.

What is claimed is:

1. A target pattern, comprising:
a main pattern; and
a compensation pattern, located at least one end of the main pattern to compensate for a rounded feature of the main pattern,
wherein the compensation pattern has an approximately rectangular pattern.

2. The target pattern according to claim 1, wherein the compensation pattern is shifted in a first direction relative to the main pattern.

3. The target pattern according to claim 2, wherein the compensation pattern does not completely compensate the rounded feature at one end of the main pattern.

4. The target pattern according to claim 2, wherein the at least one end of the main pattern has a n approximately rectangular pattern and a partially rounded feature.

5. The target pattern according to claim 4, wherein a part of the rounded feature is located on both sides of the approximately rectangular pattern in the first direction.

6. The target pattern according to claim 4, wherein the other end of the main pattern has the rounded feature.

7. The target pattern according to claim 1, wherein a size of the main pattern in a first direction is greater than a size of the compensation pattern in the first direction.

8. The target pattern according to claim 1, wherein the target pattern is a peripheral circuit arranged in a peripheral area.

9. A patterning method of forming target pattern, comprising:
forming a first core pattern on a stacked structure, wherein the stacked structure comprises a target layer, a mask layer and a spacer material layer stacked in sequence;
forming a first spacer in an opening of the first core pattern;
using the first spacer to perform a first etching process on the spacer material layer to form a spacer material pattern;
forming a second core pattern on the mask layer;
forming a second spacer in an opening of the second core pattern;
using the second spacer to perform a second etching process on the spacer material pattern to form a spacer pattern;
forming a patterned photoresist layer on the mask layer, wherein an opening of the patterned photoresist layer partially overlaps with the spacer pattern;
using the patterned photoresist layer to perform a third etching process on the mask layer; and
using the spacer pattern and the remaining mask layer to perform an etching process on the target layer to form the target pattern, wherein the spacer pattern overlaps with the remaining mask layer,
wherein a contour of at least one end of the target pattern is transferred by the spacer pattern, so that the at least one end of the target pattern has an approximately rectangular pattern.

10. The patterning method of forming target pattern according to claim 9, wherein there is a gap between the adjacent second spacers, and the gap overlaps with the spacer material pattern.

11. The patterning method of forming target pattern according to claim 10, wherein after using the second spacer to perform the etching process on the spacer material pattern, forming two spacer patterns having the gap between each other.

12. The patterning method of forming target pattern according to claim 11, wherein the gap overlaps with the opening of the patterned photoresist layer.

13. The patterning method of forming target pattern according to claim 9, wherein before using the first spacer to perform the first etching process on the spacer material layer, removing the first core pattern.

14. The patterning method of forming target pattern according to claim 9, wherein before using the second spacer to perform the second etching process on the spacer material pattern, removing the second core pattern.

15. The patterning method of forming target pattern according to claim 9, wherein the spacer pattern is shifted in a first direction relative to the remaining mask layer.

16. The patterning method of forming target pattern according to claim 9, wherein the size of the remaining mask layer in the first direction is larger than the size of the spacer pattern in the first direction.

17. The patterning method of forming target pattern according to claim 9, wherein the material of the spacer material layer comprises an oxide.

18. The patterning method of forming target pattern according to claim 9, wherein the target pattern is a peripheral circuit arranged in a peripheral area.

19. The patterning method of forming target pattern according to claim 9, wherein the material of the mask layer comprises nitride.
